(19) United States
(12) Patent Application Publication
(10) Pub. No.: US 2011/0148536 A1
(43) Pub. Date: Jun. 23, 2011

(54) CIRCUIT ARRANGEMENT OF A VOLTAGE CONTROLLED OSCILLATOR

(75) Inventors: Alessandro ITALIA, Solarino (Siracusa) (IT); Salvatore Dimartina, Noto (Siracusa) (IT); Calogero Marco Ippolito, Catania (IT); Giuseppe Palmisano, San Giovanni La Punta (Catania) (IT)

(73) Assignee: STMicroelectronics S.r.l., Agrate Brianza (IT)

(21) Appl. No.: 12/971,267

(22) Filed: Dec. 17, 2010

(30) Foreign Application Priority Data
Dec. 17, 2009 (IT) TO2009A000994

(51) Int. Cl. H03B 5/12; H05K 13/00

(52) U.S. Cl. 331/117 FE; 29/825

(57) ABSTRACT

A circuit for a voltage controlled oscillator has a bridge structure including two cross-coupled N-type transistors and two cross-coupled P-type transistors. A current mirror is coupled to the two N-type cross-coupled transistors and configured to generate a bias current. An LC resonator is coupled in parallel between the two cross-coupled N-type transistors and the two P-type cross-coupled transistors. The LC resonator includes two pairs of differential inductors mutually coupled by a mutual inductance coefficient, each pair comprising a first inductor arranged on a respective branch of an external loop, and a second inductor arranged on a respective branch of an internal loop. A first varactor is coupled to a common node and a first branch of the internal loop. A second varactor is coupled to the common node and the second branch of the internal loop.

### FIELD OF THE INVENTION

The present invention refers to a circuit for a voltage controlled oscillator (VCO). More specifically, the invention refers to a circuit for a voltage controlled oscillator including a varactor.

### BACKGROUND OF THE INVENTION

In modern digital wireless telecommunication systems, voltage controlled oscillators (VCO) represent a part for the synthesis of a carrier frequency, thanks to their use in PLL (Phase Locked Loop). In this type of application, the design of the oscillators is made particularly difficult by the high frequency of the synthesised signal, and by the constraints imposed by power consumption.

The traditional topology with LC resonators represents an approach used the most to satisfy the specifications of spectral purity and power consumption imposed by current communication standards. However, there are different aims that push for innovative topologies to be sought, such as the use of CMOS technologies with an ever smaller channel length requiring the use of ever lower supply voltage, the constraint of a low power consumption imposed by low data rate type applications for wireless sensor networks, and the desire for designing oscillator circuits with wide tuning range for broad band wireless systems.

FIG. 1 shows a circuit 1 of a broad band oscillator according to the prior art. The circuit 1 comprises a bridge structure including two cross-coupled N-type MOS transistors M₃ and M₄ and two cross-coupled P-type MOS transistor M₅ and M₆.

The circuit 1 also comprises an LC resonator 2 placed in parallel between the pairs of transistors M₃ and M₄ of the N type and M₅ and M₆ of the P type. The transistors M₃, M₄, M₅ and M₆ overall represent the active part of the circuit 1 that has the task of compensating for the losses of the LC resonator 2.

A known current mirror is indicated with 3, the mirror including a pair of transistors M₁ and M₂ to which a supply voltage V_{DD} is applied. The current mirror 3 generates a current I_{B} used to bias the circuit 1.

The same supply voltage V_{DD} is applied to the two transistors M₅ and M₆ of the P type through an associated voltage source. Alternatively, the supply voltage of the current mirror 3 is different from the supply voltage of the two transistors M₅ and M₆ of the P type.

The LC resonator 2 comprises an inductor L_{D} and two varactors C, supplied by a control voltage Vₜᵤₙₑ. The circuit 1 uses the two varactors C_{V} to control the oscillation frequency, which is equal to the resonant frequency of the LC resonator 2, in a continuous manner by modulating the control voltage Vₜᵤₙₑ.

In order to increase the variation range of the oscillation frequency, and thus obtain a broad band oscillator, the circuit 1 includes a first set 4a of capacitors C_{SW1}, . . . , C_{SWN} and a second set 4b of capacitors C_{SW1}, . . . , C_{SWN}, respectively identical to the capacitors C_{SW1}, . . . , C_{SWN} of the first set 4a. Each capacitor C_{SW1}, . . . , C_{SWN}, of the first set 4a and of the second set 4b, respectively, is connected to a respective switch M_{SW1}, . . . , M_{SWN} obtained with a MOS transistor of the N type controlled by an associated gate voltage B₁, . . . , B_{N}.

The capacitors C_{SW1}, . . . , C_{SWN} of the first set 4a and of the second set 4b make it possible to obtain a discrete variation of the oscillation frequency.

The main advantage of this approach lies in being able to obtain broad band oscillators without using a varactor with high values of the figure of merit K_{V}, where the figure of merit K_{V} is defined as follows:

$${K}_{V} = \frac{Δ {C}_{V}}{Δ {V}_{tune}}$$

where ΔC is the incremental variation of the capacity of the varactor with a ΔVtune variation of the control voltage.

Indeed, high values of K_{V} jeopardise the performance of phase noise due to the phenomenon of noise conversion AM-PM.

The main drawbacks are that the phase noise is not optimized in the different oscillation frequency sub-bands identified by the capacitors C_{SW1}-C_{SWN} of the first set 4a and of the second set 4b of capacitors, and that there is an oversize in terms of current consumption by the circuit 1 (and thus power consumption). Such an oversize is helpful in order to ensure a reliable oscillation start condition in the lower band limit, i.e. with a large capacity of the varactors C_{V} and an associated low figure of merit K_{V}.

FIG. 2 shows a circuit 1 of a broad band oscillator according to the prior art, in which similar elements have been given the same numbers as in FIG. 1. In this circuit 1 a varactor structure C_{V} with high figure of merit K_{V} is used.

In order to ameliorate the issues relative to the degradation of the phase noise due to the AM-PM effect, each varactor C_{V} is subdivided into N parts connected in parallel and each biased with an associated biasing voltage V_{B1}, . . . , V_{BN}. The resistors R_{B} and the capacitors C_{D} represent the biasing network of the varactors C_{V}. The capacitors C_{D} are used to decouple in DC the varactors C_{V} from the drain nodes of the transistors M₃, M₄, M₅ and M₆. The resistors R_{B} are biasing resistors used so as to help prevent the varactors C_{D} from short circuiting.

The circuit 1 makes it possible to linearize the figure of merit K_{V} and to minimize the maximum value of its derivative with respect to the control voltage Vₜᵤₙₑ for the same overall variation of the capacity of the varactors C_{V}. However, this leads to an increase of the phase noise.

FIG. 3 shows a circuit 1 of a broad band oscillator according to the prior art, in which similar elements have been given the same numbers as in FIGS. 1 and 2. In this circuit 1 the two varactors C, and four switched inductors L_{D1} and L_{D2} are used. The discrete variation of the oscillation frequency is therefore carried out by varying both the inductive and the capacitive components of the LC resonator 2.

In the circuit 1 of FIG. 3, the first set 4a and the second set 4b of capacitors comprises a single capacitor C_{SW1} connected to a respective switch M_{SW1} made by a MOS transistor of the N type controlled through a gate voltage B₁. The circuit 1 of FIG. 3 makes it possible to overcome the limits of the previously described circuits as far as the optimization of the phase noise and power consumption is concerned.

As mentioned above, the LC resonator 2 comprises four inductors, a first inductor L_{D1} and a second inductor L_{D2} arranged on a first branch 5 of the LC resonator 2, and a third inductor L_{D1} and a fourth inductor L_{D2} arranged on a second branch 6 of the LC resonator 2, respectively. The first branch 5 and the second branch 6 of the LC resonator 2 are connected to each other through a switch M_{SW} obtained with an N-type MOS transistor which, however, jeopardizes the quality factor of the first and the third inductor L_{D1}.

These are what cause there to be limits in terms of phase noise or excessive power consumption due to the reduction of the Q factor of the LC resonator 2. Such limits can be overcome by using a switch M_{SW} with low resistance and with great W/L ratio. This however, reduces the tuning range.

FIG. 4 shows a circuit 1 of a broad band oscillator according to the prior art, in which similar elements have been given the same numbers as in FIGS. 1, 2 and 3. In this circuit 1 an LC resonator 2 is used based on switched inductors in a parallel configuration.

Such a circuit 1 comprises two differential inductors L₁ mutually coupled by a mutual inductance coefficient M and a switch M_{SW} inserted in series with the inductor L₂. Such an approach has several advantages with respect to the previous approaches since the parallel configuration makes it possible to not degrade the quality factor of the equivalent parallel inductance due to the resistance of the switch M_{SW}. Such a configuration makes it possible to optimize the phase noise at the different oscillation frequencies and to obtain reliable start conditions avoiding oversizing of the circuit in terms of consumption and power.

The connection of the switch M_{SW} however, is not optimized, since the biasing voltage of the drain (source) of the MOS transistor which implements the switch M_{SW} is equal to V_{DD}-V_{GSPMOS} where V_{GSMOS} is the gate-source voltage of the transistor M_{SW}.

Consequently, the gate-source voltage in switching on conditions is equal to V_{GSPMOS}, and therefore the triode resistance, since the W/L ratio is fixed, is not the minimum which can potentially be reached. Such an issue can be eliminated by using complementary switches, but this leads to a substantial increase of the parasitic capacities thereof.

### SUMMARY OF THE INVENTION

The purpose of the present invention is therefore of providing a circuit of a voltage controlled oscillator that has better performance and lower power consumption with respect to the aforementioned prior art.

A circuit for a voltage controlled oscillator may comprise a bridge structure including two cross-coupled N-type transistors and two cross-coupled P-type transistors. A current mirror may be coupled to the two N-type cross-coupled transistors and configured to generate a bias current. In addition, an LC resonator coupled in parallel between the two cross-coupled N-type transistors and the two P-type cross-coupled transistors. The LC resonator comprises two pairs of differential inductors mutually coupled by a mutual inductance coefficient, each pair comprising a first inductor arranged on a respective branch of an external loop, and a second inductor arranged on a respective branch of an internal loop. A first varactor is coupled to a common node and a first branch of the internal loop. A second varactor coupled to the common node and the second branch of the internal loop.

### BRIEF DESCRIPTION OF THE DRAWINGS

Further characteristics and advantages of the invention shall become clearer from the following detailed description, given purely by way of an example and not for limiting purposes, with reference to the attached drawings in which:

FIG. 1, already described, is a schematic diagram of a circuit of a voltage controlled oscillator according to the first prior art;

FIG. 2, already described, is a schematic diagram of a circuit of a voltage controlled oscillator according to the prior art;

FIG. 3, already described, is a schematic diagram of a circuit of a voltage controlled oscillator according to the prior art;

FIG. 4, already described, is a schematic diagram of a circuit of a voltage controlled oscillator according to the prior art;

FIG. 5 is a schematic diagram of a circuit of a voltage controlled oscillator according to the present invention;

FIG. 6a is a top schematic view of an exemplary embodiment of a layout of a resonator of the circuit according to the present invention; and

FIG. 6b is a schematic diagram of the resonator of FIG. 6a.

### DETAILED DESCRIPTION OF THE PREFERRED EMBODIMENTS

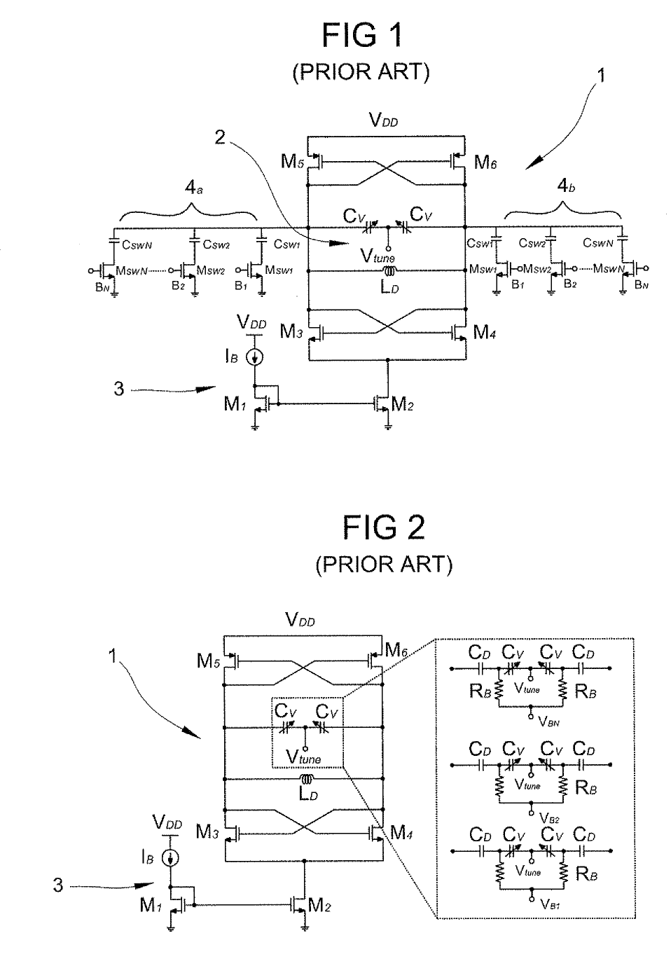

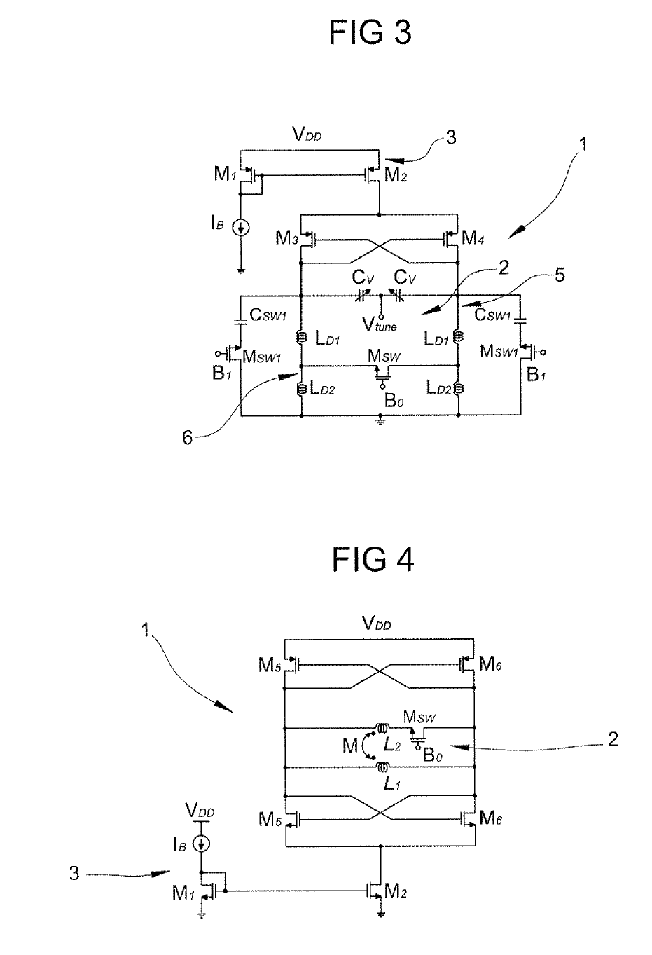

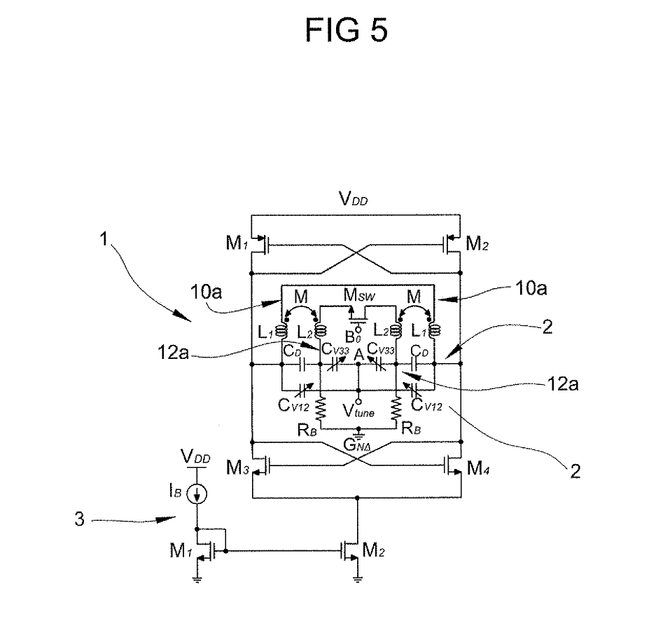

FIG. 5 illustrates a circuit of a voltage controlled oscillator according to the present invention in which similar elements have been given the same reference numerals as in FIGS. 1-4 previously described. The circuit 1 comprises a bridge structure including two cross-coupled MOS transistors M₃ and M₄ of the N type and two cross-coupled MOS transistors M₅ and M₆ of the P type.

The circuit 1 also comprises an LC resonator 2 placed in parallel between said pairs of transistors M₃ and M₄ of the N type and M₅ and M₆ of the P type. The transistors M₃, M₄, M₅ and M₆ overall represent the active part of the circuit 1 that has the task of compensating for the losses of the LC resonator 2.

The two transistors M₃ and M₄ are connected to a current mirror 3 comprising a pair of transistors Mᵢ and M₂ to which a supply voltage V_{DD} is applied. The current mirror 3 generates a current I_{B} used for biasing the circuit 1.

The same supply voltage V_{DD} is applied to the two transistors M₅ and M₆ of the P type through an associated voltage source. Alternatively, the supply voltage of the current mirror 3 is different from the supply voltage of the two transistors M₅ and M₆ of the P type.

The LC resonator circuit 2 includes two pairs of differential inductors L₁ and L₂ mutually coupled by a mutual inductance coefficient M, each pair comprising a first inductor L₁ arranged on a respective branch 10a of an external loop, and a second inductor L₂ arranged on a respective branch 12a of an internal loop. The two first inductors L₁ have a common terminal.

The two second inductors L₂ are connected to each other through a switch M_{SW} obtained with a MOS transistor of the N type biased with a gate voltage B₀. The switch M_{SW} connects or disconnects the second inductors L₂, in parallel to the first inductors L₁.

The branches 12a of the internal loop are connected to each other through a first and a second varactor C_{V33} subjected to a control voltage Vₜᵤₙₑ applied to a common node A. The branches 10a of the external loop are connected to the branches 12a of the internal loop through respective de-coupling capacitors C_{D} arranged to the decouple in DC the two second inductors L₂ and the varactors C_{V33} from the drain nodes of the transistors M₃, M₄, M₅ and M₆.

The control voltage Vₜᵤₙₑ is also connected to a third and a fourth varactor C_{V12}. The branches 12a of the internal loop are connected to a ground GND through two biasing resistances R_{B} so as to bias the switch M_{SW}, the first and the second varactor C_{V33} through the ground voltage.

The set of de-coupling capacitors C_{D} and of biasing resistors R_{B} make it possible to bias the switch M_{SW} so as to help ensure a low loss.

The linearization of the varactors C_{V12} and C_{V33} of the LC resonator 2 is carried out by obtaining the varactors C_{V12} and C_{V33} with MOS accumulation transistors with different thicknesses of oxide, the oxide thickness varying between the varactors C_{V12} and the varactor C_{V33}.

The topology of the linearized varactor therefore may not use alternative biasing points with respect to those already available in the circuit.

The bridge structure including the two cross-coupled N-type MOS transistors M₃ and M₄ and the two cross-coupled P-type MOS transistors M₅ and M₆ implements a negative resistance. Such a negative resistance has the task of compensating for the loss resistance of the LC resonator 2 so as to maintain an oscillation with constant width across said resonator 2. The oscillation frequency is determined by the following expression:

$${f}_{out} = \frac{1}{2 π \overline{{L}_{eq} {C}_{eq}}}$$

where L_{eq} and C_{eq} represent the overall equivalent inductance and the overall equivalent capacity of the circuit LC resonator 2, respectively. In order to vary the oscillation frequency in a continuous manner, the C_{eq} is varied by modifying the value of the control voltage Vₜᵤₙₑ value applied to the common node A of the varactors C_{V12} and C_{V33}. The control voltage Vₜᵤₙₑ takes on continuous values comprised between the ground voltage and the supply voltage.

In order to vary the oscillation frequency in a discrete manner, the two pairs of differential inductors L₁ and L₂ which are mutually coupled by a mutual inductance coefficient M are used. The inductance L_{eq} of the LC resonator 2 is varied in a discrete manner by activating or deactivating, in parallel to the first inductor L₁, the second inductor L₂ by using the switch M_{SW}. For this purpose the switch M_{SW} is subjected to a gate voltage B₀ that takes on two discrete values (ground voltage or supply voltage V_{DD}).

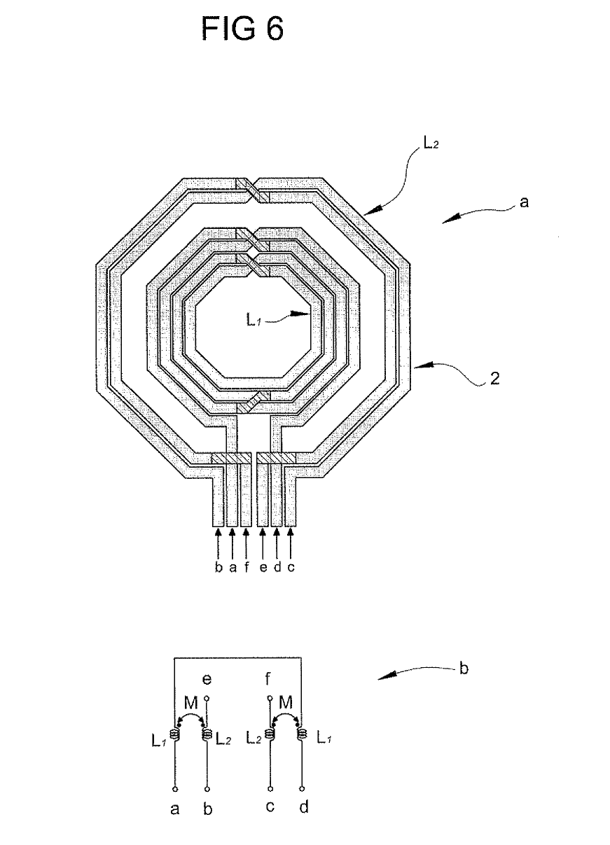

FIG. 6a illustrates a top schematic view of a layout of the resonator 2 in which the first inductors L₁ and the second inductors L₂ are obtained through two respective concentric loops of conductive material made on a silicon substrate. FIG. 6b shows the diagram of the resonator 2 in which the various terminals a-f are the same as those indicated in FIG. 6a.

Such a layout has specifically been designed so as to increase, or in some situations maximize the mutual inductance between the first inductors L₁ and the second inductors L₂ while simultaneously reducing the area of silicon they occupy.

The advantages of the circuit of a voltage controlled oscillator include optimization of the phase noise over a very high range of frequencies thanks to the topology with switched inductors and the used varactor structure, and an improvement of the tuning range with respect to the prior art thanks to the lower parasitic capacities. Further advantages include an improved trade-off between the phase noise and the tuning range thanks to the used varactor structure, minimization of the silicon area of the switched inductor structure thanks to the use of an appropriate layout, and a reduction of the power consumption of the voltage controlled oscillator thanks to the switched inductor structure.

Of course, without affecting the principle of the invention, the embodiments and the manufacture details can be widely varied with respect to what has been described and illustrated purely as a non limiting example, without for this reason departing from the scope of protection of the invention as defined in the attached claims.

1-6. (canceled)

7. A circuit for a voltage controlled oscillator comprising:
a bridge structure including two cross-coupled N-type transistors and two cross-coupled P-type transistors;
a current mirror coupled to said two N-type cross-coupled transistors and configured to generate a bias current;
an LC resonator coupled in parallel between said two cross-coupled N-type transistors and said two P-type cross-coupled transistors;
said LC resonator comprising
two pairs of differential inductors mutually coupled by a mutual inductance coefficient, each pair comprising a first inductor arranged on a respective branch of an external loop, and a second inductor arranged on a respective branch of an internal loop,
a first varactor coupled to a common node and a first branch of said internal loop, and
a second varactor coupled to said common node and said second branch of said internal loop.

8. A circuit according to claim 7, further comprising a switch comprising a N-type MOS transistor biased with a gate voltage and configured to couple said first inductor and said second inductor in parallel

9. A circuit according to claim 7, further comprising a respective de-coupling capacitor configured to decouple said two second inductors and said two varactors from said two N-type cross-coupled transistors and said two P-type cross-coupled transistors, said de-coupling capacitor coupling said branches of said external loop to said branches of said internal loop.

10. A circuit according to claim 9, further comprising two biasing resistors to couple said branches of said internal loop to a ground so as to bias said switch, said varactor, and said second varactor.

11. A circuit according to claim 7, wherein said first varactor and said second varactor are subjected to a control voltage applied to said common node.

12. A circuit according to claim 7, wherein said first inductors and said second inductors each comprise respective concentric loops of conductive material on a silicon substrate.

13. A circuit comprising:
a bridge structure including two cross-coupled N-type transistors and two cross-coupled P-type transistors;
an LC resonator coupled between said two cross-coupled N-type transistors and said two P-type cross-coupled transistors;
said LC resonator comprising
two pairs of differential inductors, each pair comprising a first inductor arranged on a respective branch of an external loop and a second inductor arranged on a respective branch of an internal loop,
a first varactor coupled to a common node and a first branch of said internal loop, and
a second varactor coupled to said common node and said second branch of said internal loop.

14. A circuit according to claim 13, further comprising a switch comprising a N-type MOS transistor biased with a gate voltage and configured to couple said first inductor and said second inductor in parallel

15. A circuit according to claim 13, further comprising a respective de-coupling capacitor configured to decouple said two second inductors and said two varactors from said two N-type cross-coupled transistors and said two P-type cross-coupled transistors, said de-coupling capacitor coupling said branches of said external loop to said branches of said internal loop.

16. A circuit according to claim 15, further comprising two biasing resistors to couple said branches of said internal loop to a ground so as to bias said switch, said varactor, and said second varactor.

17. A circuit according to claim 13, wherein said first varactor and said second varactor are subjected to a control voltage applied to said common node.

18. A circuit according to claim 13, wherein said first inductors and said second inductors each comprise respective concentric loops of conductive material on a silicon substrate.

19. A method of making a circuit for a voltage controlled oscillator comprising:
forming a bridge structure by cross-coupling two N-type transistors and cross-coupling two P-type transistors;
coupling a current mirror to the two N-type cross-coupled transistors and configured the current mirror to generate a bias current;
coupling an LC resonator in parallel between the two cross-coupled N-type transistors and the two P-type cross-coupled transistors;
the LC resonator comprising
two pairs of differential inductors mutually coupled by a mutual inductance coefficient, each pair comprising a first inductor arranged on a respective branch of an external loop, and a second inductor arranged on a respective branch of an internal loop,
a first varactor coupled to a common node and a first branch of the internal loop, and
a second varactor coupled to the common node and the second branch of the internal loop.

20. A method according to claim 19, further comprising a switch comprising a N-type MOS transistor biased with a gate voltage and configured to couple the first inductor and the second inductor in parallel

21. A method according to claim 19, further comprising a respective de-coupling capacitor configured to decouple the two second inductors and the two varactors from the two N-type cross-coupled transistors and the two P-type cross-coupled transistors, the de-coupling capacitor coupling the branches of the external loop to the branches of the internal loop.

22. A method according to claim 21, further comprising two biasing resistors to couple the branches of the internal loop to a ground so as to bias the switch, the varactor, and the second varactor.

23. A method according to claim 19, wherein the first varactor and the second varactor are subjected to a control voltage applied to the common node.

24. A method according to claim 19, wherein the first inductors and the second inductors each comprise respective concentric loops of conductive material on a silicon substrate.
